(19) United States
(12) Patent Application Publication
(10) Pub. No.: US 2025/0140227 A1
(43) Pub. Date: May 1, 2025

(54) BROADBAND SILENCER USING ACOUSTIC METAMATERIAL AND METHOD OF DESIGNING THE SAME

(71) Applicant: AJOU UNIVERSITY INDUSTRY-ACADEMIC COOPERATION FOUNDATION, Suwon-si (KR)

(72) Inventors: Jin Woo LEE, Suwon-si (KR); Jae Ho CHO, Seoul (KR)

(73) Assignee: AJOU UNIVERSITY INDUSTRY-ACADEMIC COOPERATION FOUNDATION, Suwon-si (KR)

(21) Appl. No.: 18/932,648

(22) Filed: Oct. 31, 2024

(30) Foreign Application Priority Data
Oct. 31, 2023 (KR) 10-2023-0148541

(51) Int. Cl. G10K 11/16; G10K 11/172

(52) U.S. Cl. CPC G10K 11/161; G10K 11/172

(57) ABSTRACT

A method of designing a silencer by using an acoustic metamaterial according to the present disclosure includes distributing design variables through an experimental design method, performing optimal design on initial design proposals, obtaining an insertion loss of an optimal unit cell, and selecting a unit cell to be used first for effective noise reduction.

### CROSS-REFERENCE TO RELATED APPLICATION

This application is based on and claims priority under 35 U.S.C. § 119 to Korean Patent Application No. 10-2023-0148541, filed on Oct. 31, 2023, in the Korean Intellectual Property Office, the disclosure of which is incorporated by reference herein in its entirety.

### BACKGROUND

The present disclosure relates to a wideband silencer using an acoustic metamaterial which reduces exhaust noise in a corresponding frequency band, while multiple walls forming a unit cell do not interfere with a flow of exhaust air flowing in an exhaust flow pipe, by arranging multiple units that reduce the exhaust noise in the corresponding frequency band a straight pipe structure in which the center of an inlet where exhaust air flows in coincides with an outlet where the exhaust air flows out, and to a method of designing the wideband silencer.

Noise generated from power devices has been recognized as a problem in various industrial fields and daily life.

Such noise may cause health problems, such as hearing loss, to workers performing work near apparatuses or people living in adjacent residential facilities.

Many studies have been conducted to reduce such noise, and silencers have been traditionally and widely used, especially to reduce exhaust noise generated during operations of internal combustion engines.

Silencers are widely used in the automotive and industrial fields, and mainly reduce noise by using expansion chambers, porous materials, and Helmholtz resonators.

The silencers operate on the principle of reflecting or absorbing incident noise.

However, the general silencers may provide noise reduction effects in a specific frequency range, but have limitations in wide-band noise reduction.

In particular, it is difficult for machinery with high displacement, such as vehicles or industrial machines, using large engines to form a wide noise reduction band due to acoustic characteristics.

The general silencers require a considerable expansion chamber diameter ratio (3˜4 or more) compared to a diameter of an exhaust gas flow pipe in order to achieve high and wide levels of noise reduction performance due to acoustic characteristics.

Apparatuses that use large internal combustion engines, such as tanks, submarines, industrial machines, and generators, require large flow pipes due to a high level of output required by engines, an appropriate level of exhaust speed, and high exhaust amount due to low back pressure.

When the exhaust noise of the devices is to be reduced through the general silencer design method, a size of the expansion chamber has to also be significantly increased due to a large size of the flow pipe.

In this case, the development of a silencer with a smaller expansion chamber and flow pipe diameter ratio is required in consideration of an installation space of the silencer and operability of a device.

The related art may include Korean Patent Publication No. 10-2007-0092425 (2007, 09, 13) and Korean Patent Publication No. 10-2013-0064299 (2013, 06. 18).

### SUMMARY

An object of the present disclosure is to provide a wideband silencer using an acoustic metamaterial which may effectively secure a noise reduction band and noise reduction performance even when a diameter of an expansion chamber is smaller than a diameter of a flow tube of the general silencer, may expand application of a shape of a unit cell to be used for not only reducing exhaust noise but also noise caused by a flow of the pipe, and may be extended to devices using the general acoustic metamaterials utilizing band gaps, and a method of designing a broadband silencer using an acoustic metamaterial.

According to an aspect of the present disclosure, a silencer mounted on an exhaust pipe of an internal combustion engine includes an exhaust flow pipe having an inlet formed on a first side for exhaust air of the internal combustion engine to flow in, an outlet formed on a second side for the exhaust air to flow out, and a flow path formed inside the exhaust flow pipe for the exhaust air to flow from the first side to the second side; and multiple unit cells provided inside the silencer in a longitudinal direction of the exhaust flow pipe to reduce noise in a corresponding frequency band among exhaust noises flowing along the exhaust flow pipe.

Also, each of the multiple unit cells may include a front wall elongated from the exhaust flow pipe toward a center of the exhaust flow pipe such that a lengths of the exhaust flow pipe is orthogonal to a length of the front wall, a rear wall elongated from the exhaust flow pipe toward the center of the exhaust flow pipe by a corresponding distance from the front wall to be parallel to the front wall by being separated from the front wall, a first resonance wall separated from the exhaust flow pipe by a corresponding distance and elongated from a rear of the front wall toward the rear wall to be parallel to the exhaust flow pipe, a first resonator formed by a gap width between the exhaust flow pipe and the first resonance wall that are parallel to each other, a second resonance wall separated from the first resonance wall by a corresponding distance and elongated from the rear of the front wall toward the rear wall to be parallel to the first resonance wall, a second resonator parallel formed by a gap width between the first resonance wall and the second resonance wall that are parallel to each other, a third resonance wall separated from the second resonance wall by a corresponding distance and elongated from the rear of the front wall toward the rear wall to be parallel to the second resonance wall, a third resonator formed by a gap width between the second resonance wall and the third resonance wall that are parallel to each other, a fourth resonance wall is separated from the third resonance wall by a corresponding distance and elongated from the rear of the front wall toward the rear wall to be parallel to the third resonance wall, and a fourth resonator formed by a gap width between the third resonance wall and the fourth resonance wall that are parallel to each other.

Also, a length of each of the first resonance wall to the fourth resonance wall may be determined to correspond to a frequency band of noise to be reduced.

Also, a width of each of the first resonator to the fourth resonator may be determined to correspond to a frequency band of noise to be reduced.

Also, each of the first resonator to the fourth resonator may include a neck into which the exhaust air flows along the exhaust flow pipe.

In addition, the silencer may further include wavelength tubes respectively formed in a front of the front wall and in a rear of the rear wall and having widths determined to correspond to a frequency band of noise to be reduced.

According to another aspect of the present disclosure, a method of designing a silencer by using an acoustic metamaterial includes distributing design variables through an experimental design method; performing optimal design on initial design proposals; obtaining an insertion loss of an optimal unit cell; and selecting a unit cell to be preferentially used for effective noise reduction.

Here, the selecting of the unit cell may include checking an overall sound pressure level (OASPL) of a current sound pressure, checking a degree of reduction of the overall sound pressure level according to the unit cell, selecting a unit cell that reduces the overall sound pressure level the most, and updating the current sound pressure according to the selected unit cell.

The present disclosure has an effect of a wideband silencer using an acoustic metamaterial and a method of designing the wideband silencer using the acoustic metamaterial.

Even when a diameter of an expansion chamber is less than a diameter of a flow pipe compared to the general silencer, a noise reduction band and noise reduction performance may be effectively obtained.

In addition, a shape of the unit cell used in the present disclosure may be expanded not only to reduce exhaust noise but also noises caused by air flowing through a pipe, and a method of selecting the unit cell may be expanded to all devices using the general acoustic metamaterials that utilize band gaps.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are example views illustrating a wideband silencer using an acoustic metamaterial according to an embodiment of the present disclosure;

FIGS. 2A and 2B are example views illustrating cross-sections of a basic unit cell according to an embodiment of the present disclosure;

FIGS. 3A and 3B are graphs illustrating finite element analysis results (a dispersion curve and a band gap) of a basic unit cell according to an embodiment of the present disclosure;

FIG. 4 illustrates example diagrams of insertion losses of a silencer according to an embodiment of the present disclosure;

FIG. 5 illustrates graphs of an insertion loss and a band gap of a basic unit according to an embodiment of the present disclosure;

FIG. 6 illustrates graphs of the measured exhaust noise of a silencer including a combination of basic unit cells according to an embodiment of the present disclosure;

FIG. 7 is a block diagram sequentially illustrating a method of designing a wideband silencer using an acoustic metamaterial, according to an embodiment of the present disclosure;

FIGS. 8A and 8B are example views illustrating shapes of an initial unit cell in which design variables are distributed by a method of designing a wideband silencer using an acoustic metamaterial, according to an embodiment of the present disclosure;

FIG. 9 illustrates graphs (a dispersion curve and a band gap) of an effect that may be obtained from an objective function by a method of designing a wideband silencer using an acoustic metamaterial, according to an embodiment of the present disclosure;

FIGS. 10A and 10B are example views (a shape of a unit cell, a band gap change, and an objective function change); illustrating unit cell optimization by a method of designing a wideband silencer using an acoustic metamaterial, according to an embodiment of the present disclosure;

FIGS. 11A and 11B are example views (modeling for insertion loss acquisition and insertion loss acquisition results) illustrating insertion loss results obtained by a unit cell arranged by a method of designing a wideband silencer using an acoustic metamaterial, according to an embodiment of the present disclosure;

FIG. 12 illustrates graphs illustrating insertion loss normalization by a method of designing a wideband silencer using an acoustic metamaterial, according to an embodiment of the present disclosure;

FIG. 13 illustrates graphs illustrating insertion loss normalization by a method of designing a wideband silencer using an acoustic metamaterial, according to an embodiment of the present disclosure;

FIG. 14 is a flowchart sequentially illustrating a process of selecting a specific optimal unit cell by a method of designing a wideband silencer using an acoustic metamaterial according to an embodiment of the present disclosure;

FIGS. 15A to 15D are example views (a cross-sectional shape of a unit cell, estimated insertion loss and band gap region, linearity, and noise reduction degree illustrated in a logarithmic scale) illustrating a shape and acoustic characteristics of a first unit cell selected by a method of designing a wideband silencer using an acoustic metamaterial, according to an embodiment of the present disclosure;

FIGS. 16A to 16D are example views (a cross-sectional shape of a unit cell, estimated insertion loss and band gap region, linearity, and noise reduction degree illustrated in a logarithmic scale) illustrating a shape and acoustic characteristics of a second unit cell selected by a method of designing a wideband silencer using an acoustic metamaterial, according to an embodiment of the present disclosure;

FIGS. 17A to 17D are example views (a cross-sectional shape of a unit cell, estimated insertion loss and band gap region, linearity, and noise reduction degree illustrated in a logarithmic scale) illustrating a shape and acoustic characteristics of a third unit cell selected by a method of designing a wideband silencer using an acoustic metamaterial, according to an embodiment of the present disclosure;

FIGS. 18A to 18D are example views (a cross-sectional shape of a unit cell, estimated insertion loss and band gap region, linearity, and noise reduction degree illustrated in a logarithmic scale) illustrating a shape and acoustic characteristics of a fourth unit cell selected by a method of designing a wideband silencer using an acoustic metamaterial, according to an embodiment of the present disclosure;

FIGS. 19A to 19D are example views (a cross-sectional shape of a unit cell, estimated insertion loss and band gap region, linearity, and noise reduction degree illustrated in a logarithmic scale) illustrating a shape and acoustic characteristics of a fifth unit cell selected by a method of designing a wideband silencer using an acoustic metamaterial, according to an embodiment of the present disclosure;

FIGS. 20A to 20D are example views (a cross-sectional shape of a unit cell, estimated insertion loss and band gap region, linearity, and noise reduction degree illustrated in a logarithmic scale) illustrating a shape and acoustic characteristics of a sixth unit cell selected by a method of designing a wideband silencer using an acoustic metamaterial, according to an embodiment of the present disclosure;

FIGS. 21A to 21D are example views (a cross-sectional shape of a unit cell, estimated insertion loss and band gap region, linearity, and noise reduction degree illustrated in a logarithmic scale) illustrating a shape and acoustic characteristics of a seventh unit cell selected by a method of designing a wideband silencer using an acoustic metamaterial, according to an embodiment of the present disclosure;

FIGS. 22A to 22D are example views (a cross-sectional shape of a unit cell, estimated insertion loss and band gap region, linearity, and noise reduction degree illustrated in a logarithmic scale) illustrating a shape and acoustic characteristics of an eighth unit cell selected by a method of designing a wideband silencer using an acoustic metamaterial, according to an embodiment of the present disclosure;

FIGS. 23A to 23D are example views (a cross-sectional shape of a unit cell, estimated insertion loss and band gap region, linearity, and noise reduction degree illustrated in a logarithmic scale) illustrating a shape and acoustic characteristics of a ninth unit cell selected by a method of designing a wideband silencer using an acoustic metamaterial, according to an embodiment of the present disclosure;

FIGS. 24A to 24D are example views (a cross-sectional shape of a unit cell, estimated insertion loss and band gap region, linearity, and noise reduction degree illustrated in a logarithmic scale) illustrating a shape and acoustic characteristics of a tenth unit cell selected by a method of designing a wideband silencer using an acoustic metamaterial, according to an embodiment of the present disclosure;

FIGS. 25A to 25D are example views (a cross-sectional shape of a unit cell, estimated insertion loss and band gap region, linearity, and noise reduction degree illustrated in a logarithmic scale) illustrating a shape and acoustic characteristics of an eleventh unit cell selected by a method of designing a wideband silencer using an acoustic metamaterial, according to an embodiment of the present disclosure;

FIGS. 26A to 26D are example views (a cross-sectional shape of a unit cell, estimated insertion loss and band gap region, linearity, and noise reduction degree illustrated in a logarithmic scale) illustrating a shape and acoustic characteristics of a twelfth unit cell selected by a method of designing a wideband silencer using an acoustic metamaterial, according to an embodiment of the present disclosure;

FIG. 27 illustrates example views of a silencer designed with a combination of the first to twelfth unit cells selected by a method of designing a wideband silencer using an acoustic metamaterial, according to an embodiment of the present disclosure;

FIG. 28 is a graph comparing an estimated and calculated insertion loss of a silencer designed with a combination of the first to twelfth units selected by a method of designing a broadband silencer using acoustic metamaterial according to an embodiment of the present disclosure; and

FIGS. 29A and 29B illustrate graphs comparing a noise reduction amount of a silencer designed with a combination of the first to twelfth unit cells selected by a method of designing a broadband silencer using an acoustic metamaterial, according to an embodiment of the present disclosure with a noise reduction amount of a silencer designed with a combination of basic unit cells.

### DETAILED DESCRIPTION

Hereinafter, preferred embodiments of the present disclosure will be described in detail with reference to the attached drawings. Prior to this, the terms or words used in the present specification and claims should not be interpreted as limited to their usual or dictionary meanings, and should be interpreted as meanings and concepts that conform to the technical idea of the present disclosure based on the principle that the inventor may appropriately define the concept of the term in order to explain his or her own invention in the best way.

Therefore, the embodiments described in the present specification and the configurations illustrated in the drawings are merely the most preferred embodiments of the present disclosure, and do not represent all of the technical ideas of the present disclosure, and accordingly, it should be understood that there may be equivalent modified examples that may be replaced at the time of the present application.

First, a metamaterial refers to a synthetic material that has unique properties not found in nature. A silencer includes unit cells designed in a special way and shows a unique response to waves, such as electromagnetic waves or sound waves, due to an arrangement and structure of the unit cells.

An acoustic metamaterial shows unique characteristics on sound and waves among metamaterials, and have special propagation characteristics that are not observed in general materials.

The present disclosure provides a method of designing a silencer with a relatively higher noise reduction effect and a relatively smaller volume than the general silence in a relatively wider frequency band than the general silencer by using characteristics of the acoustic metamaterial and the concept of generative design.

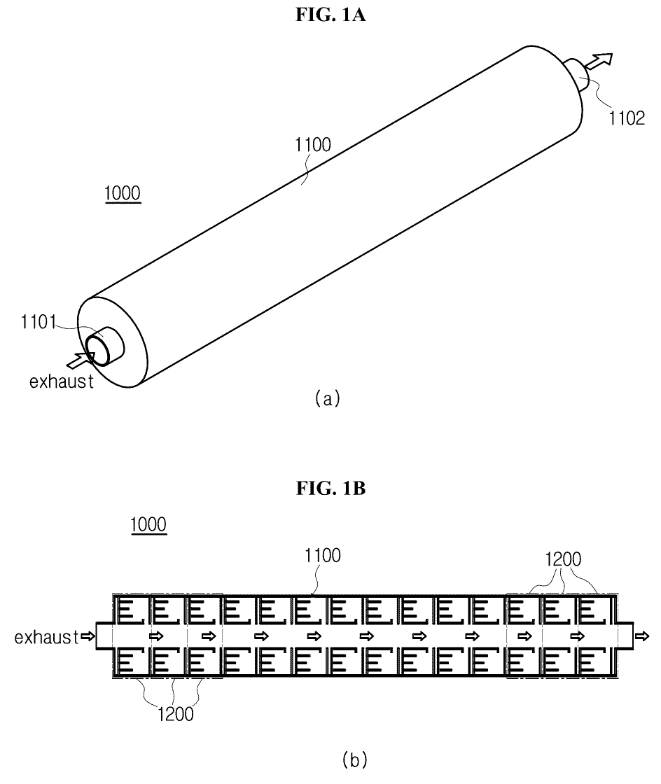

FIGS. 1A and 1B illustrate a wideband silencer using an acoustic metamaterial according to an embodiment of the present disclosure, FIG. 1A illustrates a silencer 1000 including a combination of unit cells 1200 (see FIG. 1B) that substantially reduce noise, and FIG. 1B is a cross-sectional view of the silencer 1000 illustrating internal structures of the unit cells 1200.

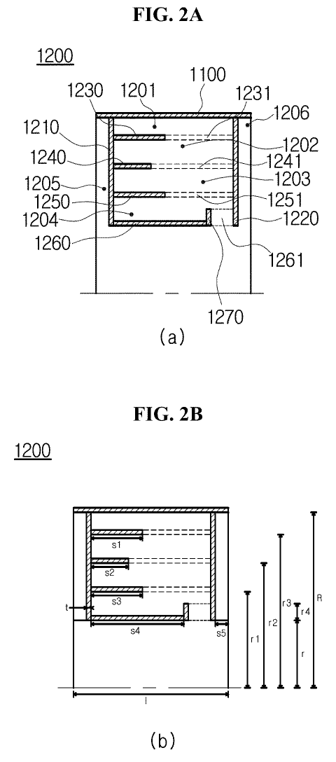

FIGS. 2A and 2B illustrate cross-sectional views of the unit cell 1200 of an acoustic metamaterial according to an embodiment of the present disclosure.

The unit cell 1200 rotates 360° based on a lower rotation axis of a cross-section of the unit cell 1200 to form a structure of the unit cell 1200, and the silencer 1000 is formed based on this.

Structures, which are composed of multiple walls 1210, 1220, 1230, 1240, 1250, and 1260 of the basic unit cell 1200 and may reduce noise, are illustrated, and each structure may form a specific noise reduction band.

In particular, a noise reduction band may be expanded or changed by adjusting lengths and positions of the walls 1210, 1220, 1230, 1240, 1250, and 1260.

The wideband silencer 1000 using an acoustic metamaterial according to an embodiment of the present disclosure with reference to FIGS. 1 and 2 includes an exhaust flow pipe 1100 and the multiple unit cells 1200, the exhaust flow pipe 1100 is a hollow pipe having an inlet 1101 formed on one side through which exhaust air of an internal combustion engine flows in and an outlet 1102 formed on an opposite side through which exhaust air flows out, and a flow passage 1203 formed inside through which exhaust air flows from one side to the other side.

In addition, multiple unit cells 1200 are formed inside in a longitudinal direction of the exhaust flow pipe 1100 and reduces noise in a corresponding frequency band among exhaust noises flowing along the exhaust flow pipe 1100.

Here, the multiple unit cells 1200 may each include a front wall 1210, a rear wall 1220, a first resonance wall 1230, a second resonance wall 1240, a third resonance wall 1250, and a fourth resonance wall 1260 to form multiple resonators 1201, 1202, 1203, and 1204 that reduce noise in a corresponding frequency band.

The front wall 1210 is elongated from the exhaust flow pipe 1100 toward the center of the exhaust flow pipe 1100, and accordingly, a length of the front wall 1210 is orthogonal to a length of the exhaust flow pipe 1100.

In addition, the rear wall 1220 is elongated from the exhaust flow pipe 1100 toward the center of the exhaust flow pipe 1100 with a corresponding distance from the front wall 1210 and is parallel to the front wall 1210 by being separated from the front wall 1210.

The first resonance wall 1230, the second resonance wall 1240, the third resonance wall 1250, and the fourth resonance wall 1260 are provided between the front wall 1210 and the rear wall 1220 which are parallel to each other, and the first resonance wall 1230 is elongated from the rear of the front wall 1210 toward the rear wall 1220 with a corresponding distance from the exhaust flow pipe 1100 and is parallel to the exhaust flow pipe 1100 by being separated from the exhaust flow pipe 1100 by a corresponding distance.

In this case, a length of the first resonance wall 1230 is determined to correspond to a noise frequency band to be reduced, and a first neck 1231 through which exhaust air (noise) flows is formed between a rear end of the length of the first resonance wall 1230 and the rear wall 1220.

In addition, a space is formed by a gap width between the exhaust flow pipe 1100 and the first resonance wall 1230 that are parallel to each other to form a first resonator 1201.

Therefore, exhaust air (noise) flows to the first resonator 1201 through the first neck 1231, and thus, noise in a corresponding frequency band is reduced.

In addition, the second resonance wall 1240 is separated from the first resonance wall 1230 by a corresponding distance, and is elongated from the rear of the front wall 1210 toward the rear wall 1220, and is parallel to the first resonance wall 1230 by being separated from the first resonance wall 1230 by a corresponding distance.

In this case, a length of the second resonance wall 1240 is determined to correspond to a noise frequency band to be reduced, and a second neck 1241 is formed between a rear end of the length of the second resonance wall 1240 and the rear wall 1220 through which exhaust air (noise) flows.

In addition, a space is formed by a gap width between the first resonance wall 1230 and the second resonance wall 1240 which are parallel to each other to form a second resonator 1202.

Therefore, exhaust air (noise) flows to the second resonator 1202 through the second neck 1241, and thus, noise in a corresponding frequency band is reduced.

In addition, the third resonance wall 1250 is separated from the second resonance wall 1240 by a corresponding distance, and is elongated from a rear of the front wall 1210 toward the rear wall 1220, and is parallel to the second resonance wall 1240 by being separated from the second resonance wall 1240 by a corresponding distance.

In this case, a length of the third resonance wall 1250 is determined to correspond to a noise frequency band to be reduced, and a third neck 1251 through which exhaust air (noise) flows is formed between a rear end of the length of the third resonance wall 1250 and the rear wall 1220.

In addition, a space is formed by a gap width between the second resonance wall 1240 and the third resonance wall 1250 that are parallel to each other to form a third resonator 1203.

Therefore, exhaust air (noise) flows through the third neck 1251 to the third resonator 1203, and thus, noise in a corresponding frequency band is reduced.

In addition, the fourth resonance wall 1260 is separated from the third resonance wall 1250 by a corresponding distance, and is elongated from the rear of the front wall 1210 toward the rear wall 1220, and is parallel to the third resonance wall 1250 by being separated from the third resonance wall 1250 by a corresponding distance.

In this case, a length of the fourth resonance wall 1260 is determined to correspond to a noise frequency band to be reduced, and a fourth neck 1261 through which exhaust air (noise) flows is formed between a rear end of the length of the fourth resonance wall 1260 and the rear wall 1220.

In addition, a space is formed by a gap width between the third resonance wall 1250 and the fourth resonance wall 1260 that are parallel to each other to form a fourth resonator 1204.

Therefore, exhaust air (noise) flows to the fourth resonator 1204 through the fourth neck 1261, and thus, noise in the corresponding frequency band is reduced.

Here, the fourth resonator 1204 is formed at an innermost side of the exhaust flow pipe 1100 to be adjacent to the center of the exhaust flow pipe 1100, the third resonator 1203 is formed on an outer circumference of the fourth resonator 1204, the second resonator 1202 is formed on an outer circumference of the third resonator 1203, and the first resonator 1201 is formed on an outer circumference of the second resonator 1202.

The unit cell 1200 according to the embodiment of the present disclosure is illustrated as an example, a length of each of the first resonance wall 1230 to the fourth resonance wall 1260 of the unit cell 1200 is determined according to a frequency band of noise to be reduced, and a width of each of the first resonator 1201 to the fourth resonator 1204 is also determined according to the frequency band of the noise to be reduced.

In addition, the unit cell 1200 may form wave channels 1205 and 1206 in front of the front wall 1210 and in the rear of the rear wall 1220, and widths of the wave channels 1205 and 1206 are also determined according to the frequency band of the noise to be reduced.

The unit cell 1200 according to the present disclosure which has the configuration described above includes two main noise reduction structures.

The first resonator 1201 to the fourth resonator 1204 and the first neck 1231 to the fourth neck 1261 constitute the unit cell 1100 and are connected in series with each other.

The front of the front wall 1210 and the rear of the rear wall 1220 are each formed as a cavity structure at the end of the unit cell 1200, and are mutually connected to form waveguides 1205 and 1206 when the unit cells 1200 are arranged.

The internal structures achieve a noise reduction effect in a specific target frequency range by adjusting a length of a corresponding wall, and provide a wide noise reduction band by using multiple structures.

Unlike the general technology in which inner walls are structurally symmetrical, when the inner walls are formed by being biased to one side to manufacture the silencer, the unit cell 1200 has an effect of reducing the difficulty of processing.

In order to check acoustic characteristics when the acoustic metamaterial is formed by using the unit cell 1200, the noise reduction band formed when the acoustic metamaterial is formed by using boundary conditions of Floquet-Bloch is as follows.

Here, an end (rear end) of the fourth resonance wall 1260 may be connected to an inner wall 1270, and it is preferable that the inner wall 1270 is connected to the end (rear end) of the fourth resonance wall 1260 so as to be perpendicular to a length of the fourth resonance wall 1260.

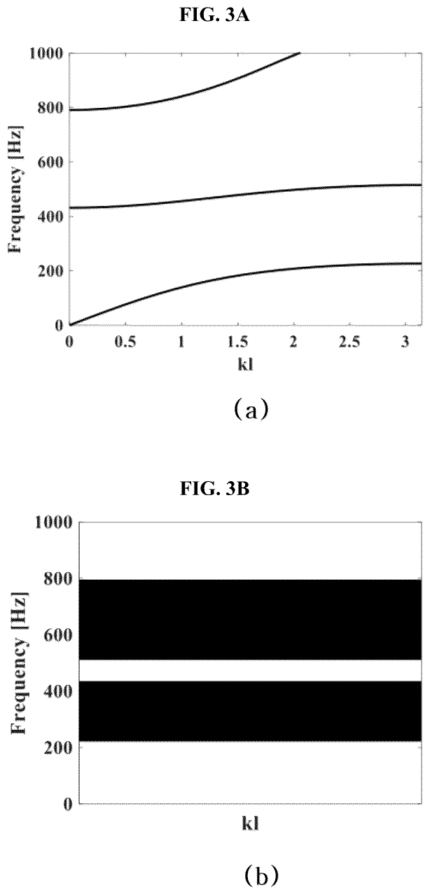

FIGS. 3A and 3B are graphs illustrating analysis results of acoustic characteristics of the unit cell 1200 using finite element analysis, FIG. 3A illustrates dispersion curves of the unit cell 1200, and the dispersion curves show a relationship between a wave number and a frequency.

A sound pressure component of the unit cell 1200 is governed by the Helmholtz equation of Equation 1 below, and an eigenvalue analysis for obtaining the dispersion curve may be obtained by finite element analysis through Equation 2 below.

$$∇ \cdot ( \frac{1}{ρ} ∇ p ) + \frac{{k}^{2}}{ρ} \cdot p = 0 \qquad Equation 1$$

Here, ρ represents density of medium (air), p represents a sound pressure, and k represents a wave number.

$$[ K - {ω}^{2} M ] p = 0 \qquad Equation 2$$

Here, K represent stiffness matrix, @ represents each wave number, M represents mass matrix, and p represents a sound pressure vector.

Although the present disclosure uses the finite element analysis to easily understand acoustic characteristics of the unit cell 1200, other methods may be used to obtain information on the dispersion curve and a band gap.

In FIG. 3B, a region where the wave number and a frequency do not correspond to each other may be checked in the graph of the dispersion curve, and this section is called a band gap, and the band gap section is a region where noise is reduced when configuring the acoustic metamaterial.

Here, referring to FIG. 4, an insertion loss and a noise reduction band of the silencer 1000 are as follows.

An insertion loss IL is used as an evaluation index to quantitatively verify noise reduction performance of the silencer 1000, is a ratio, which is expressed in a dB scale, between intensity I_{w/o} of sound passing through a noise reduction device before the noise reduction device is installed in the flow pipe and intensity I_{w} of sound passing through the noise reduction device after the noise reduction device is installed in the flow pipe, and may be defined by Equation 3 below.

$$IL = 10 log \frac{{I}_{w / o}}{{I}_{w}} \qquad Equation 3$$

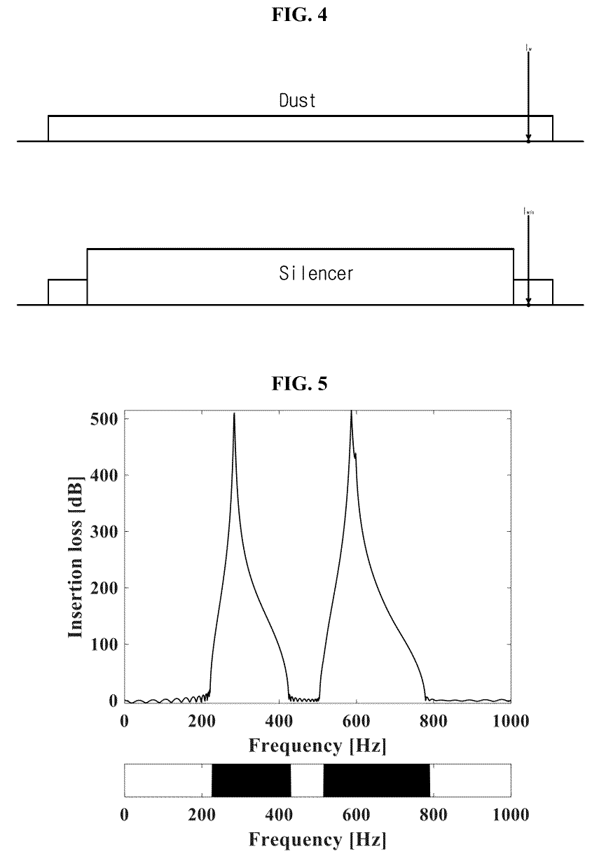

FIG. 5 illustrates the band gap section and insertion loss together which are obtained in FIG. 3, and it can be seen that a region where the band gap section is formed in the unit cell 1200 coincides with a section where an insertion loss is high.

In addition, when designing the silencer 1000, a current noise level of a target to be reduced is evaluated, and then the design is performed based on the evaluation in order to effectively form the degree of noise reduction and a reduction section.

FIG. 6 illustrates exhaust noise measurement results of a target to be reduced, FIG. 6A illustrates a linear scale thereof, and FIG. 6B illustrates a log scale thereof.

An overall sound pressure level (OASPL) of the measurement results is calculated as in Table 1 below in order to check a frequency range to be selected as a goal by using the exhaust noise measurement results.

TABLE 1

| | |
|---|---|
| Frequency range | Overall level |

| | | |
|---|---|---|
| 1~10240 | Hz | 93.6 dBA |
| 1~1000 | Hz | 93.5 dBA |
| 1000~2000 | Hz | 76.7 dBA |
| 2000~3000 | Hz | 67.2 dBA |
| 3000~4000 | Hz | 67.3 dBA |
| 4000~5000 | Hz | 63.3 dBA |
| 5000~6000 | Hz | 59.0 dBA |
| 6000~7000 | Hz | 54.5 dBA |
| 7000~8000 | Hz | 50.3 dBA |
| 8000~9000 | Hz | 48.5 dBA |
| 9000~10000 | Hz | 48.1 dBA |

The results of OASPL are results of the measured frequency range of 1 to 10240 Hz, and it can be seen that particularly high noise is formed in sections of 1 to 1000 Hz and that exhaust noise is formed to be high up to the section of 6000 Hz.

Therefore, it can be seen that the silencer 1000 has to form a noise reduction band up to 6000 Hz in order to reduce the OASPL of the exhaust noise.

Although a silencer having a normal size is relatively easy to form a noise reduction band in a narrow frequency range, an object having a large size, such as a large silencer, has a high design difficulty to form a noise reduction band in a narrow frequency range, and the difficulty of forming a wideband noise reduction band is even higher.

As a solution to the problem, the present disclosure provides the silencer 1000 with a high-performance wideband based on an acoustic metamaterial by using concept of generative design.

The generative design is a design process that generates various design proposals based on goals set by a designer and constraints and selects the most appropriate design proposal among the design proposals to meet a design purpose.

A method of designing a wideband silencer using an acoustic metamaterial according to an embodiment of the present disclosure includes a step of distributing design variables by using an experimental design method, a step of performing an optimal design for an initial design proposal, a step of obtaining an insertion loss of an optimal unit cell, and a step of selecting a unit cell to be preferentially used for effective noise reduction.

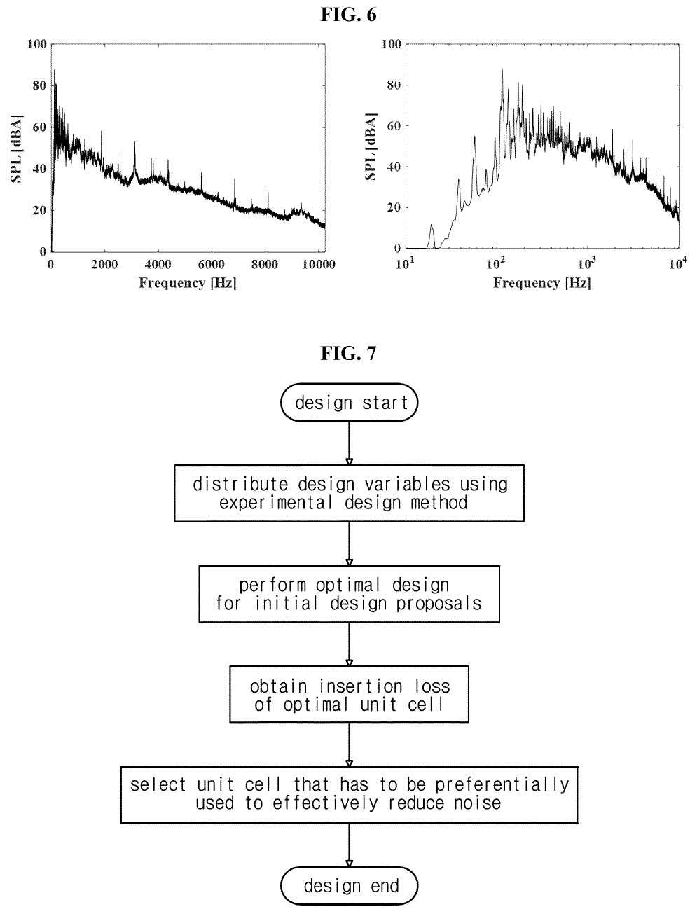

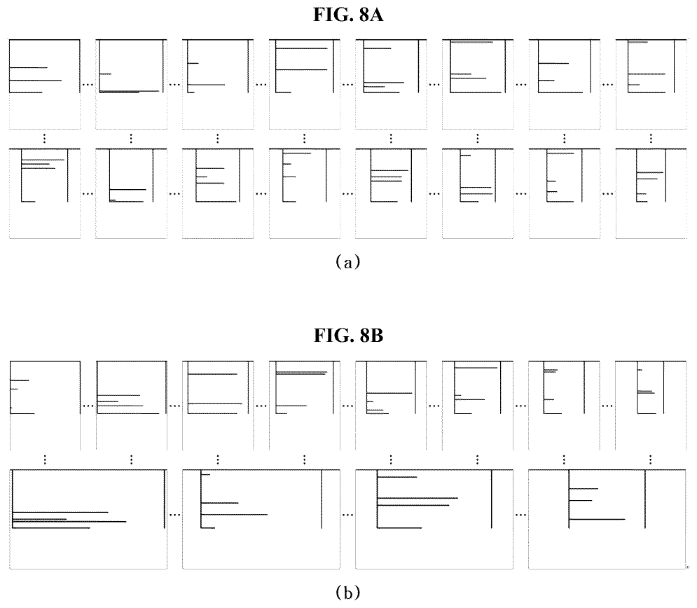

Based thereon, a silencer is designed according to a design process of FIG. 7, and at the beginning of the design, values of design variables are designated for a shape of the unit cell 1200 by using an experimental design method, and the optimal design technique is used to obtain the unit cell 1200 that has a noise reduction band over a wide frequency range.

Thereafter, insertion losses of the acquired unit cells 1200 are obtained, and the unit cell 1200 that has to be preferentially used to reduce the OASPL of the exhaust noise among the unit cells 1200 is used to configure the silencer 1000.

The above experimental design method is a statistical method for designing an effective data acquisition process, and is used to identify a relationship between various experimental factors and various levels.

Because the optimal design result may change depending on an initial value of a design variable, the initial shapes are effectively generated by using the experimental design method to generate the unit cell 1200 of various noise reduction bands.

In this process, the experimental design method may set initial design variables of the unit cells 1200 by using the Latin hypercube sampling design.

In order to effectively configure the silencer 1000, the unit cells 1200 are classified into two categories: a low frequency band and a mid-high frequency band.

In addition, a length of the unit cell 1200 that reduces a low frequency is 200 mm or 400 mm, and it is preferable to set the length of the unit cell 1200 for the medium-high frequency band to 200 mm.

The unit cell 1200 is configured by using a resonator structure, and the larger the size of an internal cavity of the resonator structure, the easier to form a noise reduction band in the low frequency band.

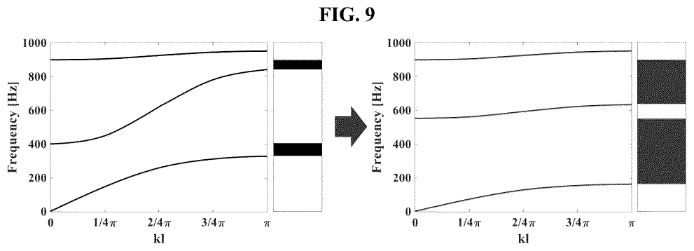

When designating the initial design variables, 200 unit design plans are generated for each frequency band, and the unit cell 1200 generated from this process is illustrated in FIG. 8.

The optimal design technique is a design method for deriving an optimal design for a given design problem, and the technique is used to form a noise reduction band in a wide frequency range.

In order to form a noise reduction band within a target frequency range for an optimal design of the unit cell 1200, an objective function L may be defined as in Equation 4 below.

$$Min L \\ L = {\sum }_{n = 1}^{N} {α}_{n} \cdot {( min ( fn ) - max ( fn ) )}^{2} \\ max ( fn ) \leq fa \qquad Equation 4$$

The objective function of Equation 4 is calculated by squaring a difference between a maximum value and a minimum value of each n-th order dispersion curve component fn obtained from an eigenvalue analysis of the unit cell 1200 and by calculating N-th order dispersion curve components that interpret the calculation result by summing weights an up to a target frequency fa.

As illustrated in FIG. 9, when using the objective function, a region where the dispersion curve is not formed in the optimization process of the unit cell 1200 may be minimized, and as a result, band gap regions within a target frequency may be expanded.

Here, a target frequency of the unit cell 1200 with a mid-high frequency is set to 6000 Hz, and a target frequency of the unit cell 1200 with a low frequency is set to 75 Hz, 150 Hz, and 300 Hz.

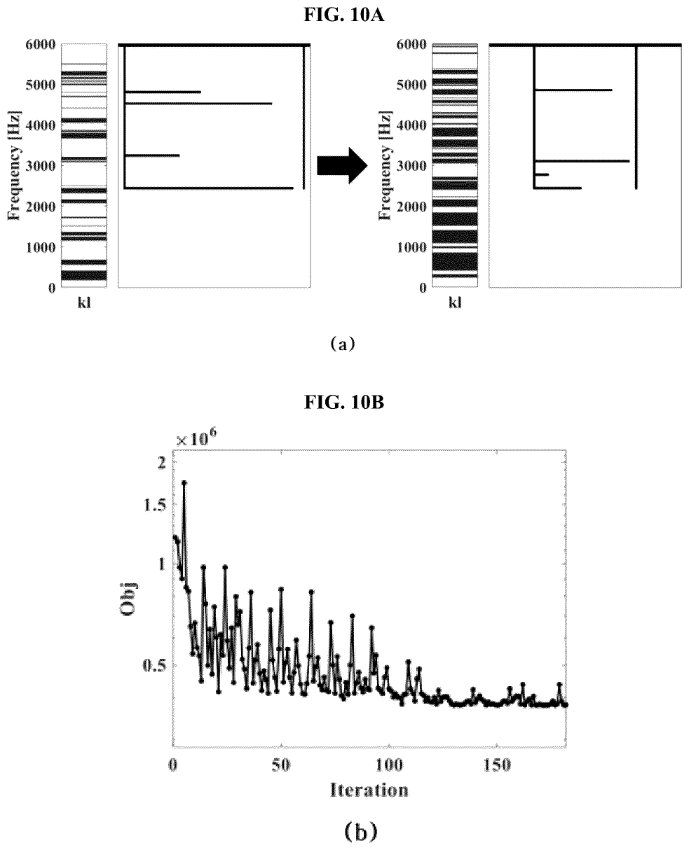

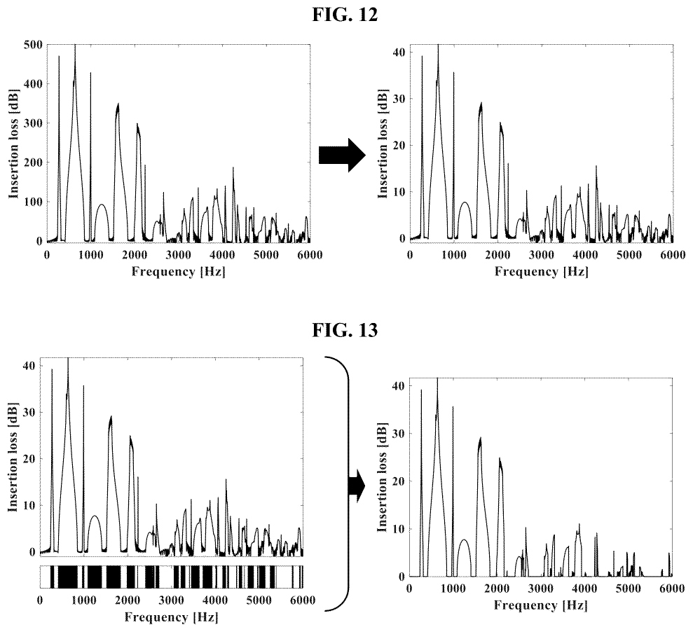

FIGS. 10A and 10B illustrate optimization results of one of the unit cell of FIG. 12 by performing the optimal design of the unit cell 1200 based on the previously set objective function, and a left side of FIG. 10A illustrates an initial shape of the unit cell and corresponding band gap sections.

Although an initially set unit cell forms a total noise reduction band of 1283 Hz in the frequency range of 1 to 6000 Hz, after optimization using the objective function, a noise reduction band of 2874 Hz is formed in the same frequency range.

Therethrough, it can be seen that a significant expansion of the noise reduction band may be made through optimization using the objective function.

FIG. 10B illustrates a graph showing a change in objective function during the optimal design process, and it can be seen that a convergence result is significantly lower than the initially calculated value of the objective function.

The process is applied to a total of 400 unit cells 1200 including 200 unit cells with a low frequency and 200 unit cells with a mid-high frequency to derive shapes of optimal unit cells 1200 having a wide noise reduction band.

The following is a process of obtaining insertion loss of the unit cells 1200, and after obtaining optimal unit cells 1200 that may each form a wide noise reduction band through the above-described process, an insertion loss is obtained when the optimal unit cells are arranged to form the silencer 1000.

The insertion loss may be calculated in the same way as the method introduced in FIG. 4 but may be obtained more efficiently by using Equation 5 below.

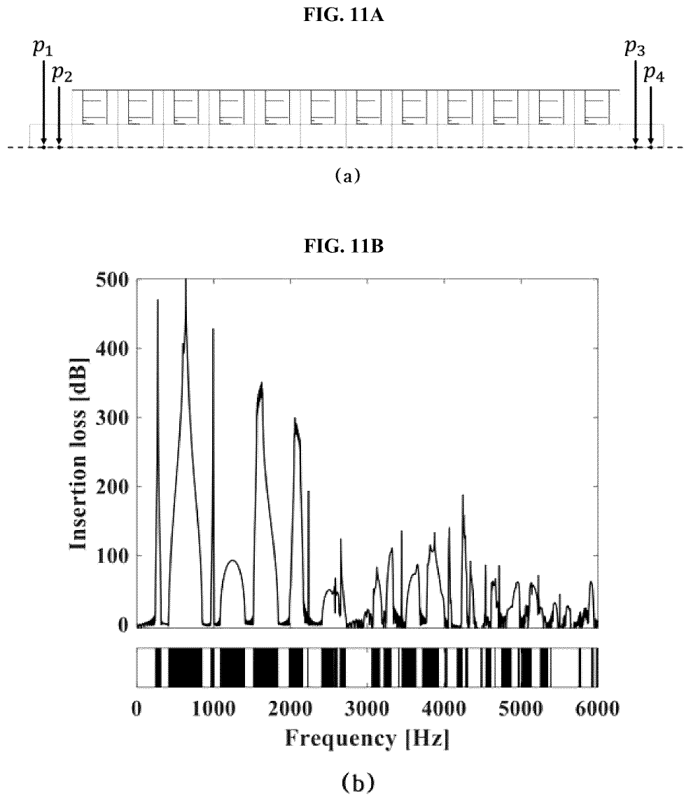

FIG. 11A illustrates analysis conditions of 4-Microphone method for obtaining an insertion loss, and this method obtains a sound pressure at four positions placed in the exhaust flow pipe 1100 of the silencer 1000, and the insertion loss may be obtained by substituting the data into Equation 5 below.

$$IL = 20 {log}_{10} \vert \frac{( {p}_{1} {e}^{{jkd}_{1}} - {p}_{2} ) ( {e}^{{jkd}_{2}} - {e}^{- {jkd}_{2}} )}{( {p}_{3} {e}^{{jkd}_{2}} - {p}_{4} ) ( {e}^{{jkd}_{1}} - {e}^{- {jkd}_{1}} )} \vert \qquad Equation 5$$

In this case, p1 to p4 represent sound pressure components measured at four measurement positions, d1 and d2 are respectively an interval between p1 and p2 and an interval between p3 and p4.

The unit cells 1200 are used in two types of a length of 200 mm and a length of 400 mm, the unit cells 1200 each having a length of 200 mm are arranged in 12 pieces as in FIG. 11a, and the unit cells 1200 each having a length of 400 mm are arranged in six pieces to calculate an insertion loss.

In this process, the number of unit cells 1200 is not specifically determined, and it is preferable to repeatedly arrange at least two or more unit cells 1200 in order to implement characteristics of metamaterials.

In the present disclosure, it is preferable to use 12 unit cells 1200 and six unit cells 1200 in consideration of a length of the silencer 1000 to be finally configured.

When selecting the unit cells 1200 for constituting the future silencer 1200, the unit cells 1200 for constituting the silencer 1000 are determined by using the estimated value of the insertion loss that may be obtained with one unit cell 1200.

Accordingly, the insertion loss obtained for each unit cell 1200 may be normalized by being classified according to the number of unit cells 1200.

FIG. 12 illustrates a normalization process of an insertion loss, and as illustrated in FIG. 11, when the insertion loss is obtained with an array of 12 unit cells 1200, the obtained IL is divided by 12 to be normalized, and when the insertion loss is obtained with an array of 6, the result is divided by 6.

FIG. 13 illustrates a result of displaying the previously obtained normalized insertion loss only in a region where the band gap is formed.

By using information of the band gap section and the normalized insertion loss, a section where the insertion loss is formed and a reduction level thereof may be more accurately identified when using the unit cell 1200.

By performing the process on the 400 unit cells that are manufactured, an estimated value of the insertion loss generated from the use of each of the unit cells 1200 may be obtained.

After completing the above-described process, a process of selecting a unit cell is as follows.

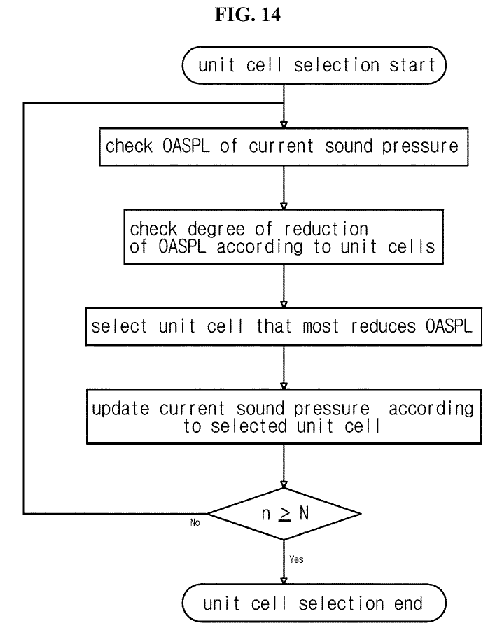

As illustrated in FIG. 14, the process of selecting the unit cell 1200 includes a step of checking a current sound pressure OASPL, a step of checking the degree of reduction of the OASPL according to the unit cells 1200, a step of selecting the unit cell 1200 that reduces the OASPL the most, and a step of updating the current sound pressure according to the selected unit cell 1200.

First, the OASPL is obtained from the current sound pressure level (SPL) of a target to be reduced as represented by Equation 6 below.

In this case, when the unit cell 1200 is selected for the first time, the measured sound pressure level of the target to be reduced is used.

$$O A S P {L}_{n} = 20 log ( \sqrt{{{\sum }^{F}}_{f} {( {p}_{n} ( f ) )}^{2}} / {P}_{ref} ) \qquad Equation 6$$

In this case, OASPLₙ is the OASPL calculated from a reduced sound pressure when Pₙ estimated when the silencer 1000 is configured by using the selected first to n-th unit cells 1200, and P_{ref} is a reference sound pressure of 20□ Pa of a resonator.

Thereafter, when each unit 1200 is used for the generated data of R unit cells 1200, an estimated reduction amount ΔOASPLₑₛₜ₍ᵣ₎ of the OASPL is checked by using following Equation 7.

$$O A S P {L}_{est ( r )} = 20 log ( \sqrt{{{\sum }^{F}}_{f} {( pef \sqrt{10 \frac{1}{10} ( S P {L}_{n} ( f ) - 1 {L}_{r} ( f ) )} )}^{2}} / Pref ) \\ △ O A S P {L}_{est ( r )} = O A S P {L}_{n} - O A S P {L}_{est ( r )} \qquad Equation 7$$

In this case, SPLₙ (f) is a reduced sound pressure level estimated from the first to n-th unit cells, and ILᵣ (f) is a normalized insertion loss of the n-th unit cell among R optimal unit cell data sets.

After the calculation on R data sets is completed, the unit cell 1200 that may form the highest □OASPLₑₛₜ₍ᵣ₎ is selected and used as the n-th unit cell 1200.

After the unit cell 1200 is selected as described above, the current SPL is updated according to Equation 8 below.

$$△ O A S P {L}_{est ( r )} = O A S P {L}_{n} - O A S P {L}_{est ( r )} \qquad Equation 8$$

The above selection process is repeated until the number of currently selected unit cells 1200 satisfies constraints (the number of unit cells) of the designated silencer 1000.

Hereinafter, an example of designing a wideband and high-performance silencer by using a method of designing a wideband silencer using an acoustic metamaterial according to an embodiment of the present disclosure is as follows.

First, when the OASPL of the measured exhaust noise illustrated in FIG. 6 is measured as 93.6 dBA, the unit cell 1200 is selected by using an estimated value of an insertion loss when the unit cell 1200 is used by using the measured SPL and OASPL.

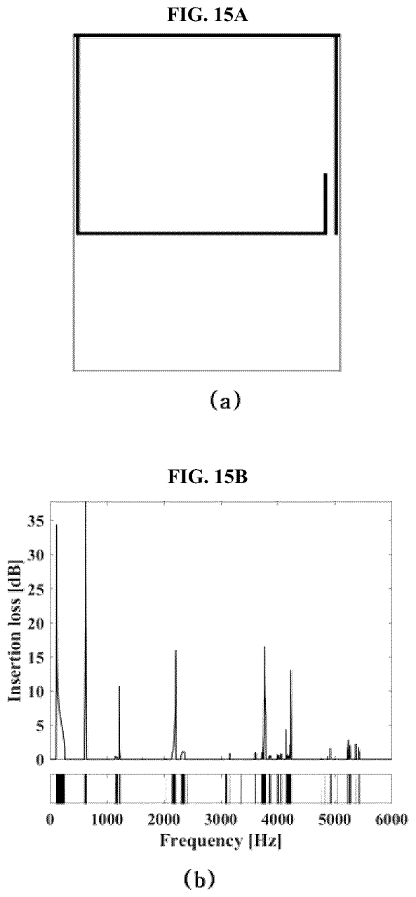

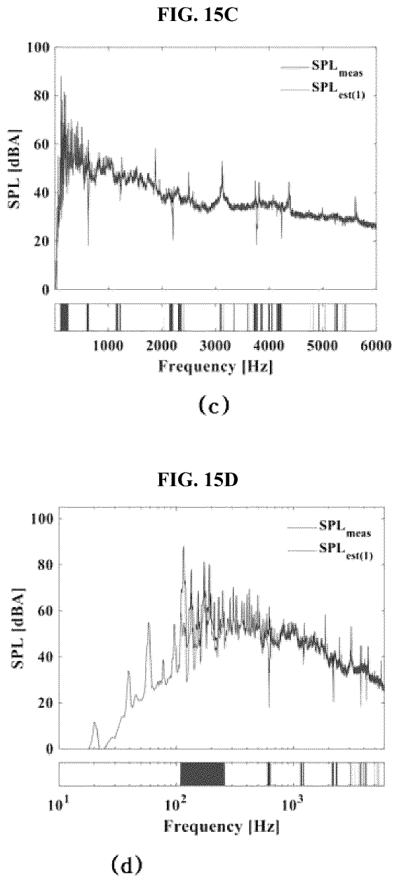

FIGS. 15A to 15D illustrate the first unit cell selected first, FIG. 15A is a cross-sectional shape of the first unit cell selected first, the first unit cell is designed to form a noise reduction band in a low-frequency band, and an insertion loss that may be obtained by using this unit cell is as illustrated in FIG. 15B.

By using this, it is expected that an OASPL is reduced by 7.1 dBA from 93.6 dBA to 86.5 dBA, and the measured exhaust noise and the reduced sound pressure level estimated by using the first unit cell are respectively illustrated in a linear scale and a logarithmic scale respectively in FIGS. 15C and 15D.

The first unit cell may form a noise reduction band of 831 Hz in a frequency range of 1 to 6000 Hz.

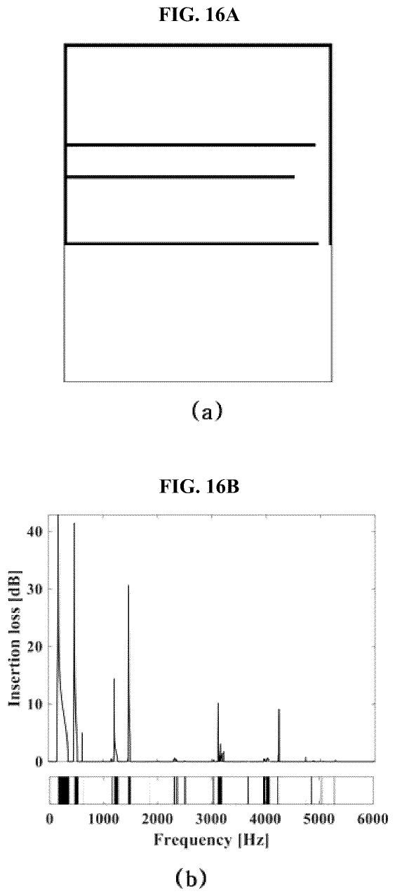

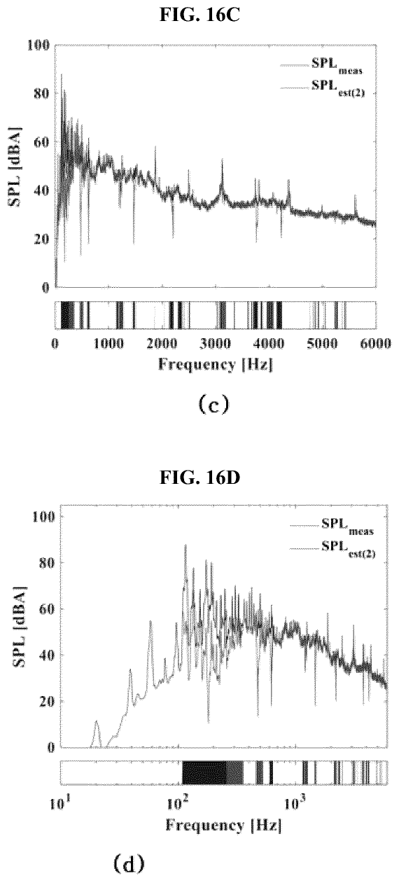

FIGS. 16A to 16D illustrate the second unit cell selected second, FIG. 16A is a cross-sectional shape of the second unit cell, and FIG. 16B illustrates an insertion loss that may be expected when a silencer is configured with the second unit cell.

By using the first unit cell and the second unit cell, an OASPL may be reduced from 93.6 dBA to 83.3 dBA, and the OASPL may be additionally reduced by 3.2 dBA compared to when the first unit cell is used alone.

When a silencer is configured with the measured exhaust noise, expected sound pressure levels are illustrated in FIGS. 16C and 16D.

The second unit cell forms a noise reduction band of 773 Hz in a frequency range of 1 to 6000 Hz, and a noise reduction band of 1351 Hz may be formed in the same frequency range by using the first and second unit cells.

A previous band gap section is marked in red at a lower portion of the insertion loss, and a newly formed band gap region is marked in blue.

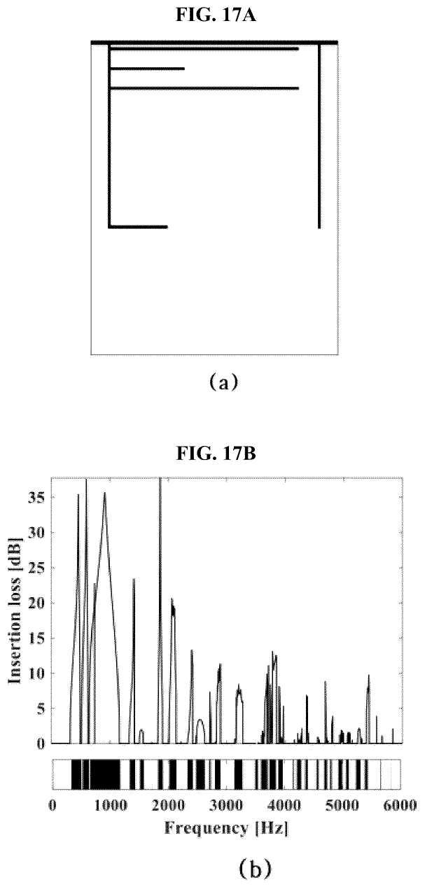

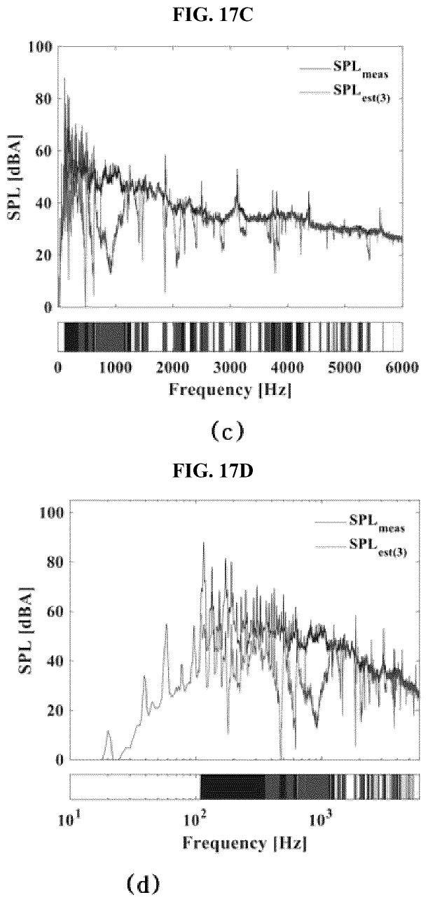

FIGS. 17A to 17D illustrate the third unit cell selected third, FIG. 17A is a cross-sectional shape of the third unit cell, and FIG. 17B illustrates an insertion loss that may be expected when a silencer is configured with the third unit cell.

By using the first to third unit cells, an OASPL may be reduced from 93.6 dBA to 78.5 dBA, and the OASPL may be additionally reduced by 4.8 dBA compared to when the first and second unit cells are used.

When a silencer is configured with the measured exhaust noise, expected sound pressure levels are illustrated in FIGS. 17C and 17D.

The third unit cell forms a noise reduction band of 2504 Hz in a frequency range of 1 to 6000 Hz, and a noise reduction band of 3375 Hz may be formed in the same frequency range by using the first to third unit cells.

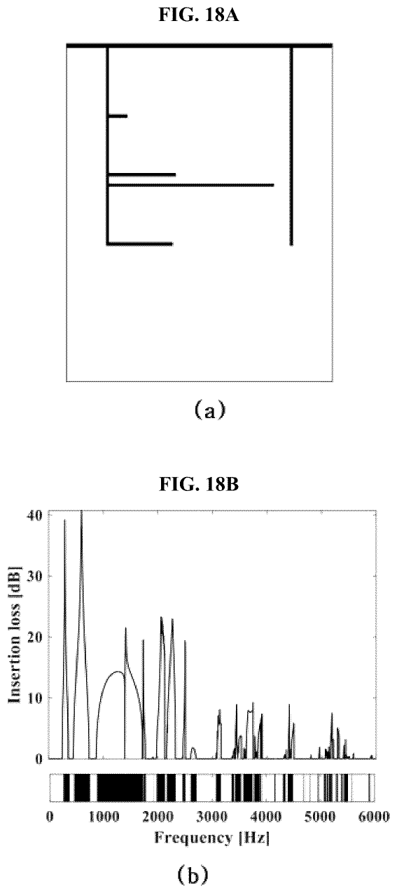

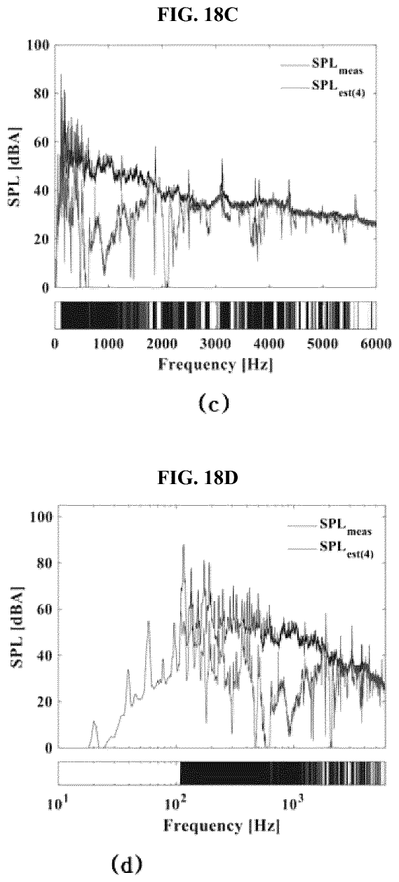

FIGS. 18A to 18D illustrate the fourth unit cell selected fourth, FIG. 18A is a cross-sectional shape of the fourth unit cell, and FIG. 18B illustrates an insertion loss that may be expected when a silencer is configured with the fourth unit cell.

By using the first to fourth unit cells, an OASPL may be reduced from 93.6 dBA to 75.3 dBA, and the OASPL may be additionally reduced by 3.2 dBA compared to when the first to third unit cells are used.

When a silencer is configured with the measured exhaust noise, expected sound pressure levels are illustrated in FIGS. 18C and 18D.

The fourth unit cell forms a noise reduction band of 2786 Hz in a frequency range of 1 to 6000 Hz, and a noise reduction band of 4397 Hz may be formed in the same frequency range by using the first to fourth unit cells.

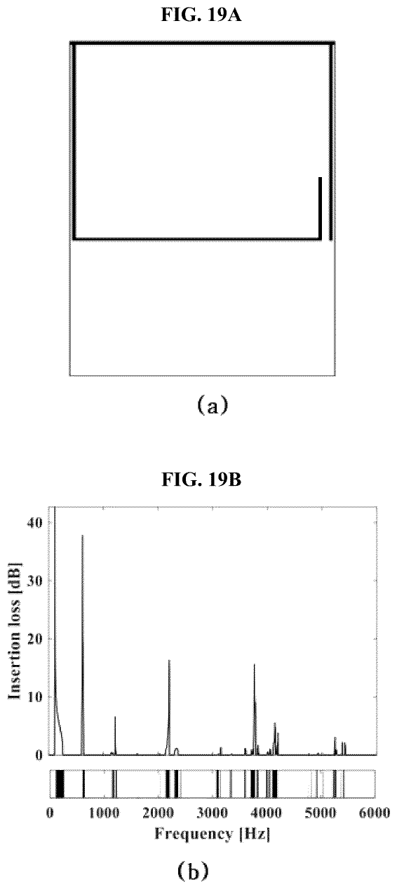

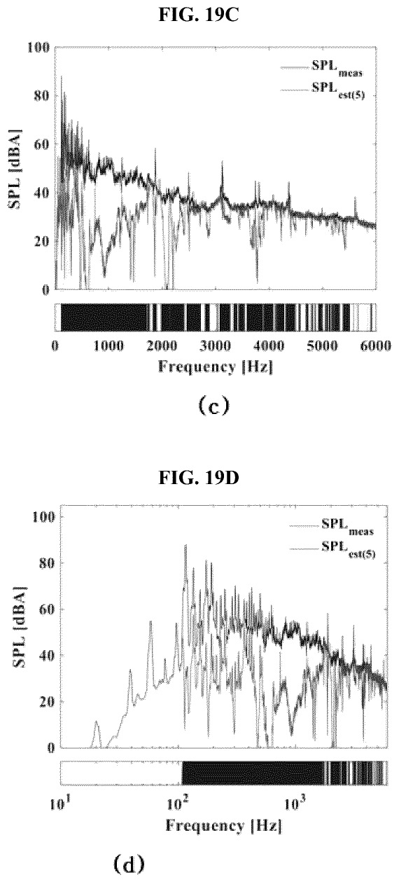

FIGS. 19A to 19D illustrate the fifth unit cell selected fifth, FIG. 19A is a cross-sectional shape of the fifth unit cell, and FIG. 19B illustrates an insertion loss that may be expected when a silencer is configured with the fifth unit cell.

By using the first to fifth unit cells, an OASPL may be reduced from 93.6 dBA to 72.3 dBA, and the OASPL may be additionally reduced by 3.0 dBA compared to when the first to fourth unit cells are used.

When a silencer is configured with the measured exhaust noise, expected sound pressure levels are illustrated in FIGS. 19C and 19D.

The fifth unit cell forms a noise reduction band of 848 Hz in a frequency range of 1 to 6000 Hz, and a noise reduction band of 4455 Hz may be formed in the same frequency range by using the first to fifth unit cells.

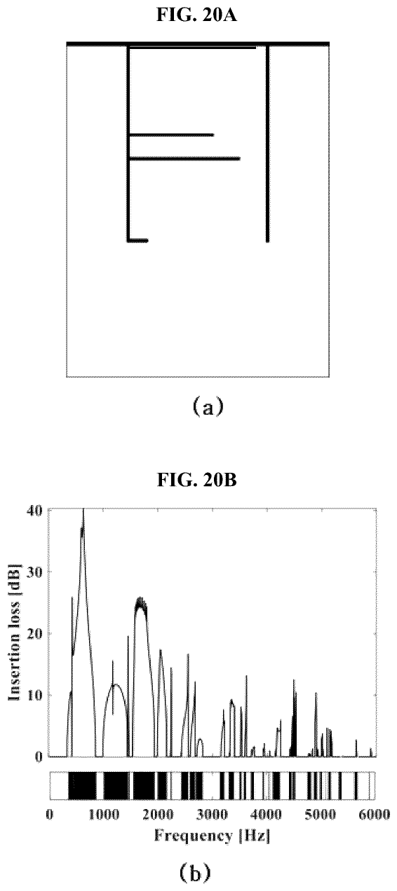

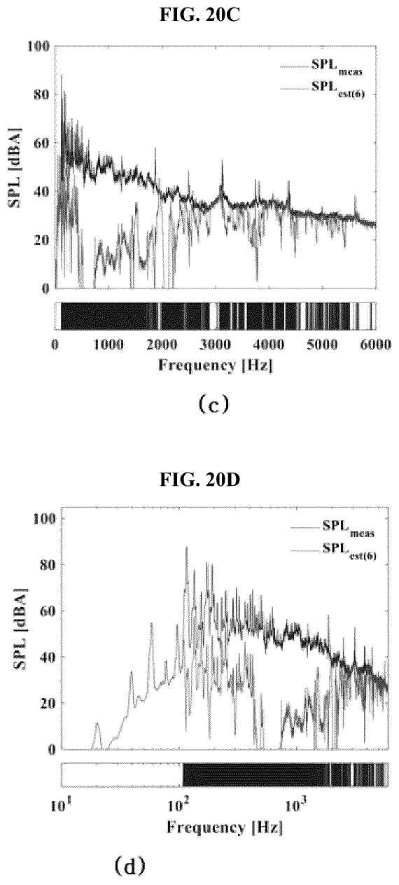

FIGS. 20A to 20D illustrate the sixth unit cell selected sixth, FIG. 20A is a cross-sectional shape of the sixth unit cell, and FIG. 20B illustrates an insertion loss that may be expected when a silencer is configured with the sixth unit cell.

By using the first to sixth unit cells, an OASPL may be reduced from 93.6 dBA to 70.1 dBA, and the OASPL may be additionally reduced by 2.2 dBA compared to when the first to fifth unit cells are used.

When a silencer is configured with the measured exhaust noise, expected sound pressure levels are illustrated in FIGS. 20C and 20D.

The sixth unit cell forms a noise reduction band of 2841 Hz in a frequency range of 1 to 6000 Hz, and a noise reduction band of 4926 Hz may be formed in the same frequency range by using the first to sixth unit cells.

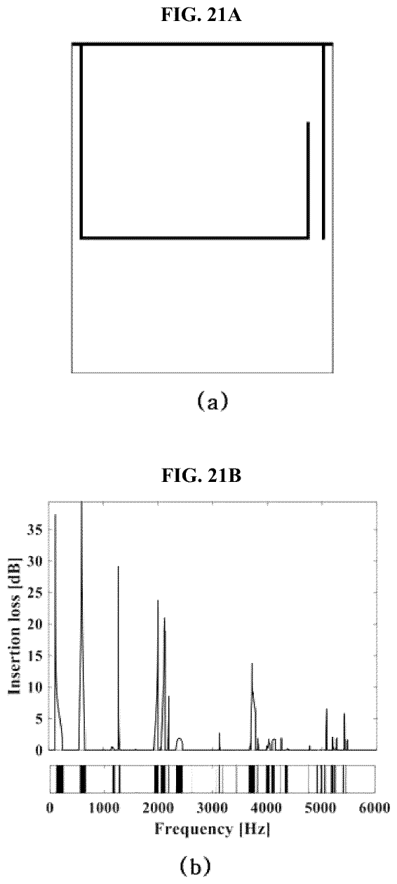

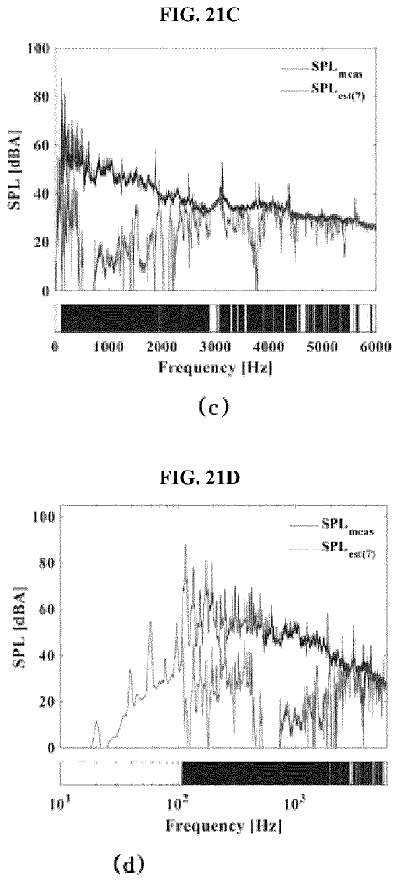

FIGS. 21A to 21D illustrate the seventh unit cell selected seventh, FIG. 21A is a cross-sectional shape of the seventh unit cell, and FIG. 21B illustrates an insertion loss that may be expected when a silencer is configured with the seventh unit cell.

By using the first to seventh unit cells, an OASPL may be reduced from 93.6 dBA to 68.9 dBA, and the OASPL may be additionally reduced by 1.2 dBA compared to when the first to sixth unit cells are used.

When a silencer is configured with the measured exhaust noise, expected sound pressure levels are illustrated in FIGS. 21C and 21D.

The seventh unit cell forms a noise reduction band of 1163 Hz in a frequency range of 1 to 6000 Hz, and a noise reduction band of 5003 Hz may be formed in the same frequency range by using the first to seventh unit cells.

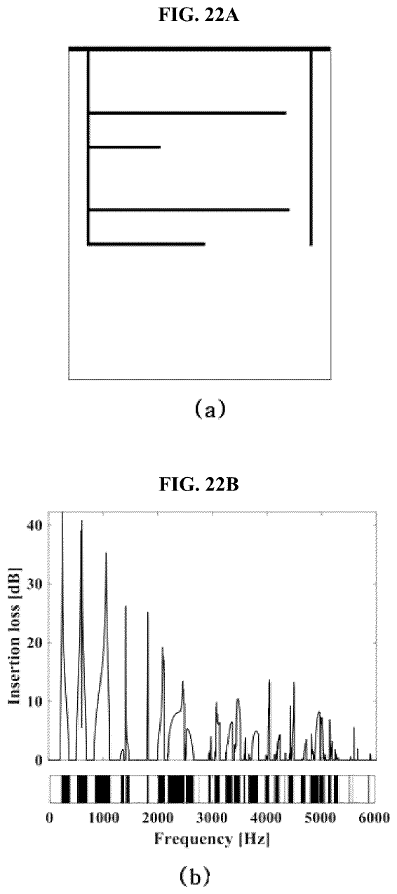

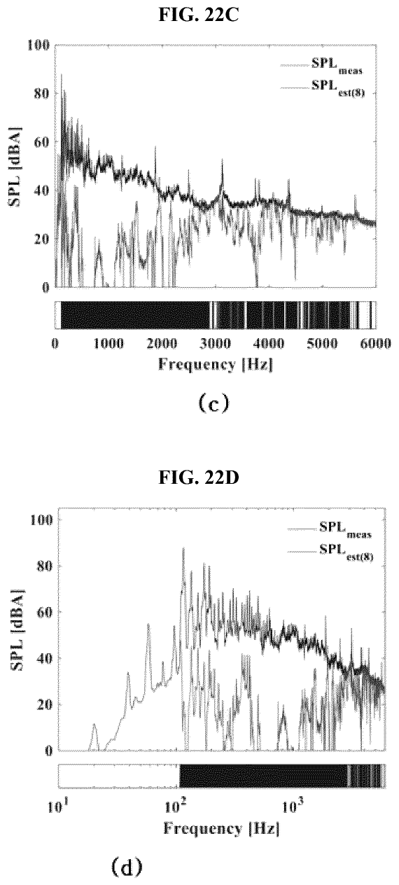

FIGS. 22A to 22D illustrate the eighth unit cell selected eighth, FIG. 22A is a cross-sectional shape of the eighth unit cell, and FIG. 22B illustrates an insertion loss that may be expected when a silencer is configured with the eighth unit cell.

By using the first to eighth unit cells, an OASPL may be reduced from 93.6 dBA to 67.6 dBA, and the OASPL may be additionally reduced by 1.3 dBA compared to when the first to seventh unit cells are used.

When a silencer is configured with the measured exhaust noise, expected sound pressure levels are illustrated in FIGS. 22C and 22D.

The eighth unit cell forms a noise reduction band of 2722 Hz in a frequency range of 1 to 6000 Hz, and a noise reduction band of 5245 Hz may be formed in the same frequency range by using the first to eighth unit cells.

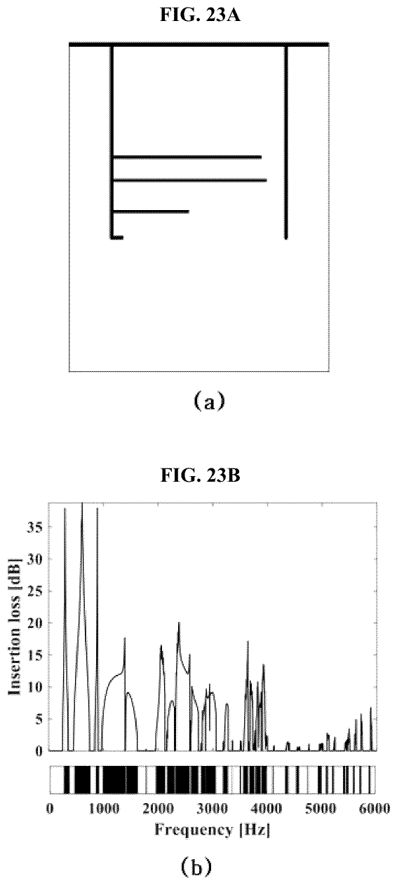

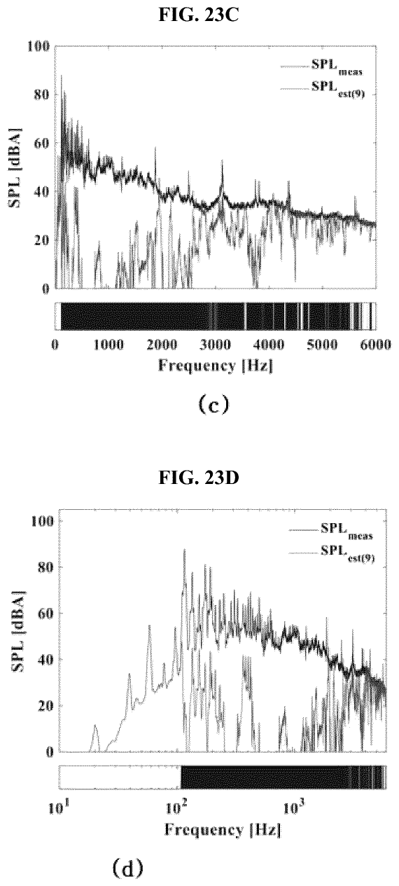

FIGS. 23A to 23D illustrate the ninth unit cell selected ninth, FIG. 23A is a cross-sectional shape of the ninth unit cell, and FIG. 23B illustrates an insertion loss that may be expected when a silencer is configured with the ninth unit cell.

By using the first to ninth unit cells, an OASPL may be reduced from 93.6 dBA to 66.7 dBA, and the OASPL may be additionally reduced by 0.9 dBA compared to when the first to eighth unit cells are used.

When a silencer is configured with the measured exhaust noise, expected sound pressure levels are illustrated in FIGS. 23C and 23D.

The ninth unit cell forms a noise reduction band of 3049 Hz in a frequency range of 1 to 6000 Hz, and a noise reduction band of 5451 Hz may be formed in the same frequency range by using the first to ninth unit cells.

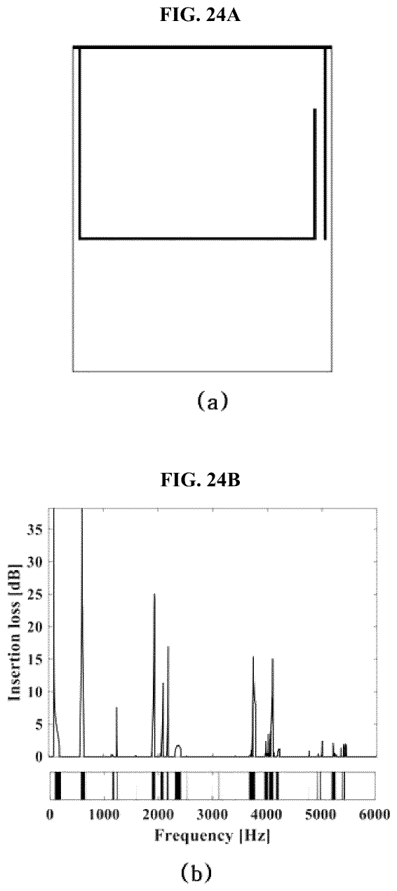

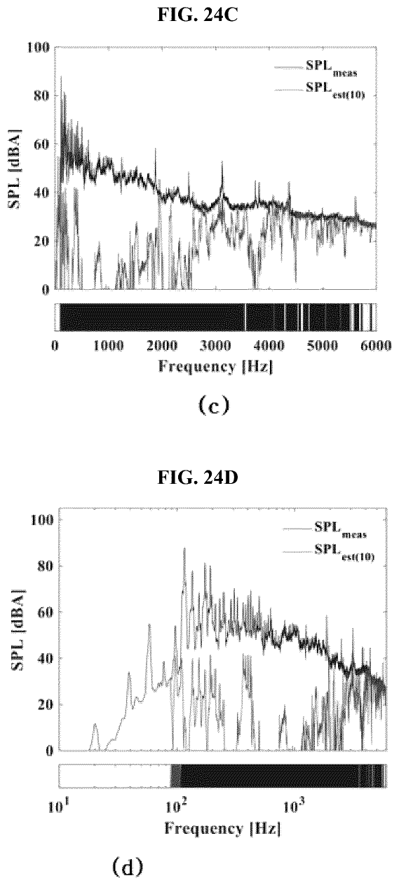

FIGS. 24A to 24D illustrate the tenth unit cell selected tenth, FIG. 24A is a cross-sectional shape of the tenth unit cell, and FIG. 24B illustrates an insertion loss that may be expected when a silencer is configured with the tenth unit cell.

By using the first to tenth unit cells, an OASPL may be reduced from 93.6 dBA to 65.5 dBA, and the OASPL may be additionally reduced by 1.2 dBA compared to when the first to ninth unit cells are used.

When a silencer is configured with the measured exhaust noise, expected sound pressure levels are illustrated in FIGS. 24C and 24D.

The tenth unit cell forms a noise reduction band of 935 Hz in a frequency range of 1 to 6000 Hz, and a noise reduction band of 5479 Hz may be formed in the same frequency range by using the first to tenth unit cells.

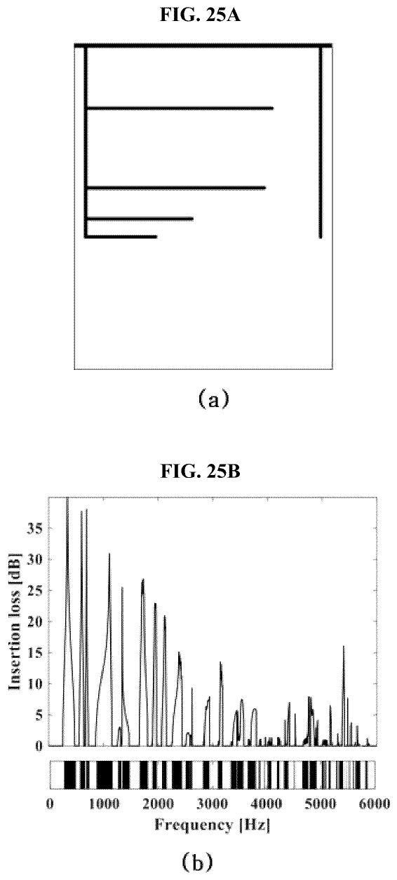

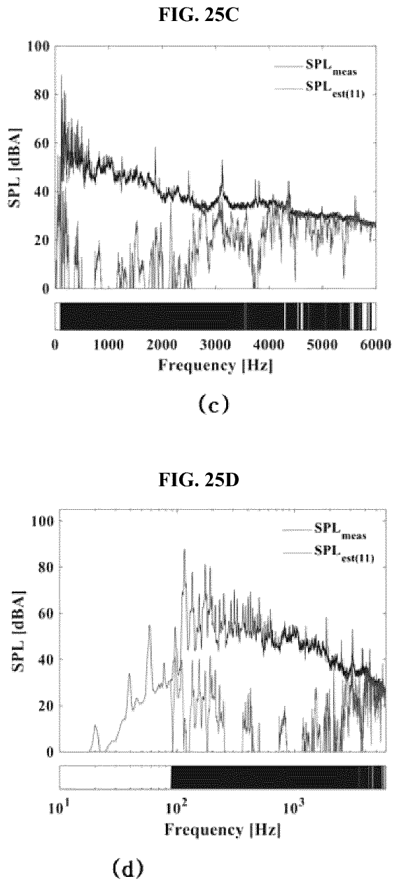

FIGS. 25A to 25D illustrate the eleventh unit cell selected eleventh, FIG. 25A is a cross-sectional shape of the eleventh unit cell, and FIG. 25B illustrates an insertion loss that may be expected when a silencer is configured with the eleventh unit cell.

By using the first to eleventh unit cells, an OASPL may be reduced from 93.6 dBA to 64.6 dBA, and the OASPL may be additionally reduced by 0.9 dBA compared to when the first to tenth unit cells are used.

When a silencer is configured with the measured exhaust noise, expected sound pressure levels are illustrated in FIGS. 25C and 25D.

The eleventh unit cell forms a noise reduction band of 2870 Hz in a frequency range of 1 to 6000 Hz, and a noise reduction band of 5586 Hz may be formed in the same frequency range by using the first to eleventh unit cells.

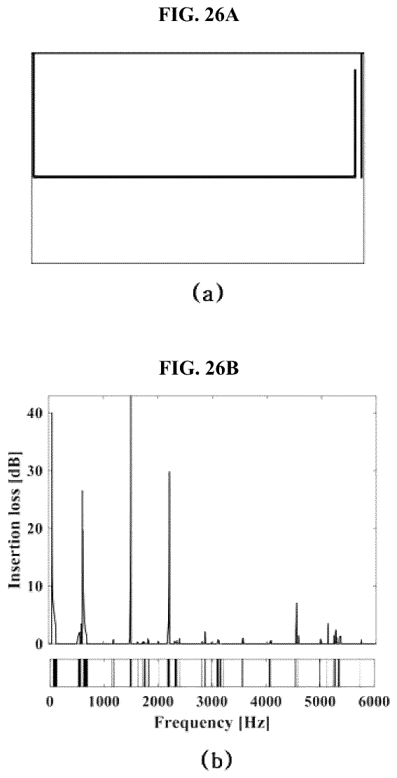

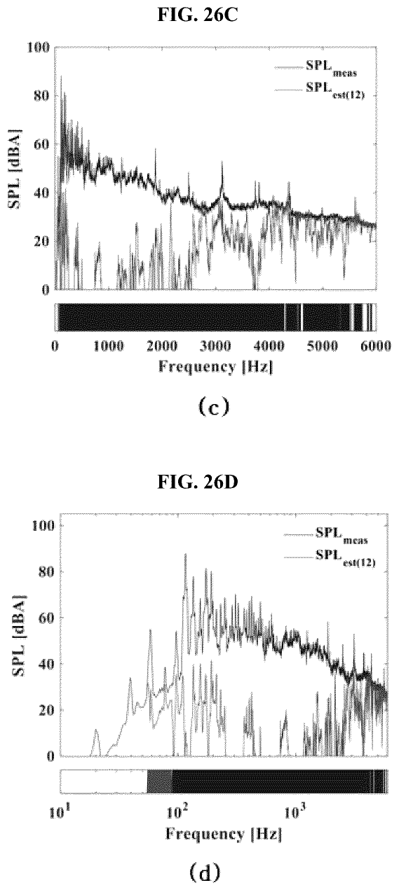

FIGS. 26A to 26D illustrate the twelfth unit cell selected twelfth, FIG. 26A is a cross-sectional shape of the twelfth unit cell, and FIG. 26B illustrates an insertion loss that may be expected when a silencer is configured with the twelfth unit cell.

By using the first to twelfth unit cells, an OASPL may be reduced from 93.6 dBA to 63.3 dBA, and the OASPL may be additionally reduced by 1.3 dBA compared to when the first to eleventh unit cells are used.

When a silencer is configured with the measured exhaust noise, expected sound pressure levels are illustrated in FIGS. 26C and 26D.

The twelfth unit cell forms a noise reduction band of 683 Hz in a frequency range of 1 to 6000 Hz, and a noise reduction band of 5637 Hz may be formed in the same frequency range by using the first to twelfth unit cells.

Table 2 below illustrates specific dimensions (unit: mm) of the selected first to twelfth unit cells.

TABLE 2

| Index | 1 | s1 | s2 | s3 | s4 | s5 | r1 | r2 | r3 | r4 |
|---|---|---|---|---|---|---|---|---|---|---|
| First | 200 | 0 | 0 | 0 | 184 | 2 | 0 | 0 | 0 | 44 |
| unit cell | | | | | | | | | | |
| Second | 200 | 0 | 186 | 170 | 188 | 0 | 0 | 177 | 153 | 0 |
| unit cell | | | | | | | | | | |
| Third | 200 | 152 | 60 | 152 | 46 | 14 | 247 | 231 | 215 | 0 |
| unit cell | | | | | | | | | | |
| Fourth | 200 | 14 | 50 | 124 | 48 | 30 | 199 | 155 | 147 | 0 |
| unit cell | | | | | | | | | | |
| Fifth | 200 | 0 | 0 | 0 | 184 | 2 | 0 | 0 | 0 | 46 |
| unit cell | | | | | | | | | | |
| Sixth | 200 | 96 | 64 | 84 | 14 | 46 | 249 | 183 | 165 | 0 |
| unit cell | | | | | | | | | | |
| Seventh | 200 | 0 | 0 | 0 | 172 | 88 | 0 | 0 | 0 | 88 |
| unit cell | | | | | | | | | | |
| Eighth | 200 | 150 | 54 | 152 | 88 | 14 | 203 | 177 | 129 | 0 |
| unit cell | | | | | | | | | | |
| Ninth | 200 | 114 | 118 | 58 | 8 | 32 | 165 | 147 | 123 | 0 |
| unit cell | | | | | | | | | | |
| Tenth | 200 | 0 | 0 | 0 | 180 | 4 | 0 | 0 | 0 | 100 |
| unit cell | | | | | | | | | | |
| Eleventh | 200 | 144 | 138 | 82 | 54 | 8 | 203 | 141 | 117 | 0 |
| unit cell | | | | | | | | | | |
| Twelfth | 400 | 0 | 0 | 0 | 384 | 2 | 0 | 0 | 0 | 128 |
| unit cell | | | | | | | | | | |

Table 3 below illustrates band gap ranges and noise reduction amounts of the selected first to twelfth unit cells.

TABLE 3

| | Bandgap | Accumu- | | |
|---|---|---|---|---|
| | section | lated band | | |
| | (Hz) | gap (Hz) | OASPL(dBA) | ΔOASPL(dBA) |
| First unit cell | 831 | 831 | 86.5 | 7.1 |
| Second unit | 773 | 1351 | 83.3 | 10.3 |
| cell | | | | |
| Third unit cell | 2504 | 3375 | 78.5 | 15.1 |
| Fourth unit | 2786 | 4397 | 75.3 | 18.3 |
| cell | | | | |
| Fifth unit cell | 848 | 4455 | 72.3 | 21.3 |
| Sixth unit cell | 2841 | 4926 | 70.1 | 23.5 |
| Seventh unit | 1163 | 5003 | 68.9 | 24.4 |
| cell | | | | |
| Eighth unit cell | 2722 | 5245 | 67.6 | 25.7 |
| Ninth unit cell | 3049 | 5451 | 66.7 | 26.6 |
| Tenth unit cell | 935 | 5479 | 65.5 | 27.8 |
| Eleventh unit | 2870 | 5586 | 64.6 | 28.7 |
| cell | | | | |
| Twelfth unit | 683 | 5637 | 63.3 | 30.3 |
| cell | | | | |

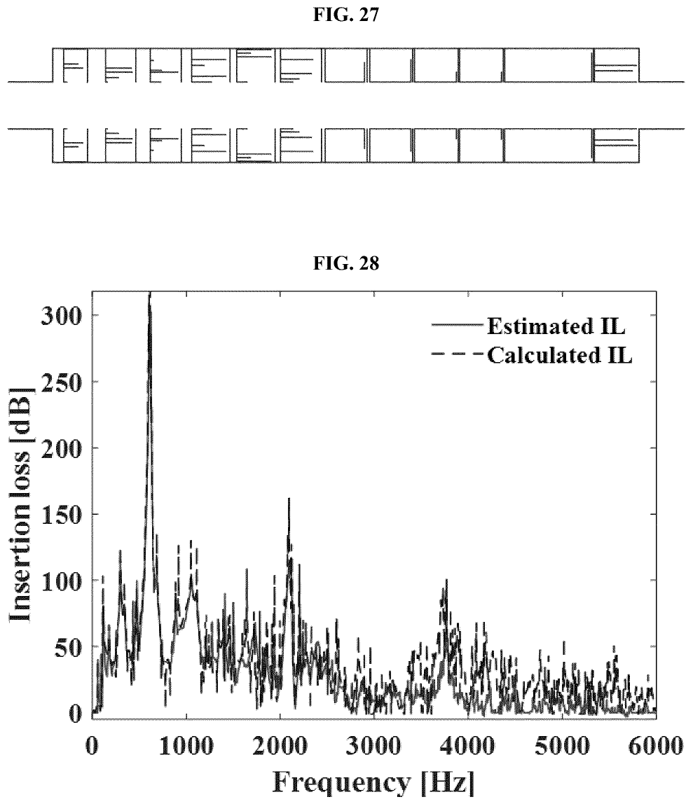

FIG. 27 illustrate results of configuring silencers by using the first to twelfth unit cells 1200 selected as described above.

An upper portion of FIG. 27 illustrates an external shape of the silencer 1000, and a lower portion of FIG. 27 illustrates a cross-sectional shape illustrating an internal shape of the silencer 1000 by removing some of components of the silencer 1000.

An acoustic metamaterial is assumed to have periodicity when being configured, and in order to maintain the periodicity as much as possible, widths of waveguide structures constituting respective unit cells are arranged in a similar order.

In order to check whether the insertion loss estimated during a selection process of each unit cell matches an actual insertion loss, a finite element analysis was performed on a designed silencer, and two results are compared with each other in FIG. 28.

It can be seen that the two results are quite similar, and when the cosine similarity (minimum: 0, maximum: 1) as in Equation 9 below is used to quantitatively evaluate the similarity of the two results, it can be seen that two values are quite similar at 0.9408.

$$cs = \frac{{IL}_{est} \cdot {IL}_{calc}}{‖ {IL}_{est} ‖ \cdot ‖ {IL}_{calc} ‖} \qquad Equation 9$$

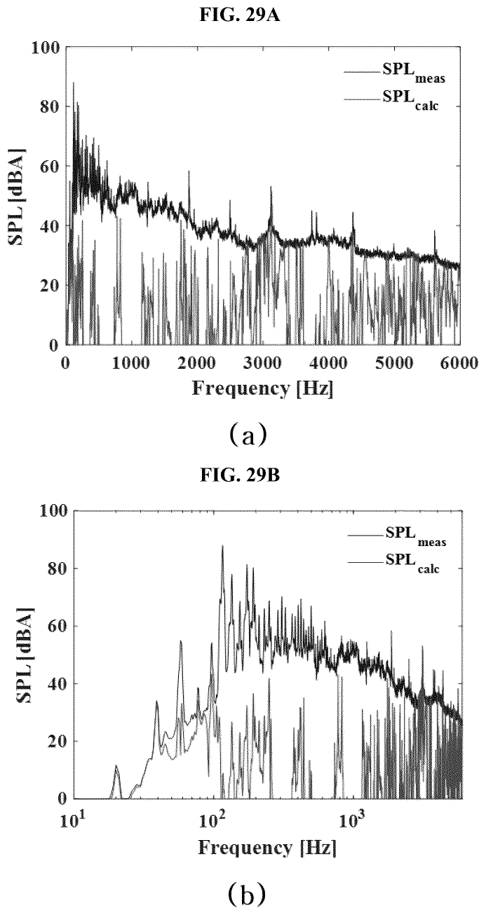

FIGS. 29A and 29B illustrate graphs in which results of insertion loss obtained from the finite element analysis of the constructed silencer are illustrated in a linear scale and a logarithmic scale.

In this case, an OASPL obtained from the analysis results is 62.9 dBA, which may reduce noise by 30.7 dBA compared to 93.6 dBA before using the silencer.

A silencer that provides high noise reduction performance in a wide frequency range by using an acoustic metamaterial according to an embodiment of the present disclosure is provided, and a method of designing the silencer is a method of designing a silencer that has a wide noise reduction band and provides high noise reduction performance by using a concept of generative design on a shape of an initial unit cell of the acoustic metamaterial.

Multiple unit cells that reduce exhaust noise in a corresponding frequency band are arranged in a straight pipe structure in which the center of an inlet where exhaust air flows coincides with the center of an outlet where exhaust air flows out, multiple walls constituting the unit cell do not interfere with the flow of the exhaust air flowing through an exhaust flow pipe and reduce exhaust noise in a corresponding frequency band, and thus, exhaust noise may be reduced.

A silencer designed in this way may effectively secure a noise reduction band and noise reduction performance even when a diameter of an expansion chamber is less than a diameter of a flow pipe compared to the general silencer.

A shape of the unit cell used in the present disclosure may be expanded not only to reduce exhaust noise but also noises caused by air flowing through a pipe, and a method of selecting the unit cell may be expanded to all devices using the general acoustic metamaterials that utilize band gaps.

The present disclosure is described with reference to the embodiments illustrated in the drawings, and the embodiments are merely examples, and those skilled in the art will understand that various modifications and equivalent other embodiments may be derived therefrom. Therefore, the true technical protection scope of the present disclosure should be determined by the technical idea of the appended patent claims.

What is claimed is:

1. A silencer mounted on an exhaust pipe of an internal combustion engine, comprising:
an exhaust flow pipe having an inlet formed on a first side for exhaust air of the internal combustion engine to flow in, an outlet formed on a second side for the exhaust air to flow out, and a flow path formed inside the exhaust flow pipe for the exhaust air to flow from the first side to the second side; and
multiple unit cells provided inside the silencer in a longitudinal direction of the exhaust flow pipe to reduce noise in a corresponding frequency band among exhaust noises flowing along the exhaust flow pipe.

2. The silencer of claim 1, wherein each of the multiple unit cells includes:
a front wall elongated from the exhaust flow pipe toward a center of the exhaust flow pipe such that a lengths of the exhaust flow pipe is orthogonal to a length of the front wall;
a rear wall elongated from the exhaust flow pipe toward the center of the exhaust flow pipe by a corresponding distance from the front wall to be parallel to the front wall by being separated from the front wall;
a first resonance wall separated from the exhaust flow pipe by a corresponding distance and elongated from a rear of the front wall toward the rear wall to be parallel to the exhaust flow pipe;
a first resonator formed by a gap width between the exhaust flow pipe and the first resonance wall that are parallel to each other;
a second resonance wall separated from the first resonance wall by a corresponding distance and elongated from the rear of the front wall toward the rear wall to be parallel to the first resonance wall;
a second resonator parallel formed by a gap width between the first resonance wall and the second resonance wall that are parallel to each other;
a third resonance wall separated from the second resonance wall by a corresponding distance and elongated from the rear of the front wall toward the rear wall to be parallel to the second resonance wall;
a third resonator formed by a gap width between the second resonance wall and the third resonance wall that are parallel to each other;
a fourth resonance wall is separated from the third resonance wall by a corresponding distance and elongated from the rear of the front wall toward the rear wall to be parallel to the third resonance wall; and
a fourth resonator formed by a gap width between the third resonance wall and the fourth resonance wall that are parallel to each other.

3. The silencer of claim 2, wherein
a length of each of the first resonance wall to the fourth resonance wall is determined to correspond to a frequency band of noise to be reduced.

4. The silencer of claim 2, wherein
a width of each of the first resonator to the fourth resonator is determined to correspond to a frequency band of noise to be reduced.

5. The silencer of claim 4, wherein
each of the first resonator to the fourth resonator includes a neck into which the exhaust air flows along the exhaust flow pipe.

6. The silencer of claim 2, further comprising:
wavelength tubes respectively formed in a front of the front wall and in a rear of the rear wall and having widths determined to correspond to a frequency band of noise to be reduced.

7. A method of designing a silencer by using an acoustic metamaterial, the method comprising:
distributing design variables through an experimental design method;
performing optimal design on initial design proposals;
obtaining an insertion loss of an optimal unit cell; and
selecting a unit cell to be preferentially used for effective noise reduction.

8. The method of claim 7, wherein the selecting of the unit cell includes:
checking an overall sound pressure level (OASPL) of a current sound pressure;
checking a degree of reduction of the overall sound pressure level according to the unit cell;
selecting a unit cell that reduces the overall sound pressure level the most; and
updating the current sound pressure according to the selected unit cell.
